(19) United States
(12) Patent Application Publication
(10) Pub. No.: US 2019/0135129 A1
(43) Pub. Date: May 9, 2019

(54) BATTERY CRADLE AND BATTERY CRADLE ASSEMBLY

(71) Applicant: Horizon Hobby, LLC, Champaign, IL (US)

(72) Inventors: Wojciech Nodzykowski, Bourne End (GB); Adam Skelding, North Wingfield (GB); Jami Jones, Cromford (GB); Jason Dearden, Ashby de la Zouch (GB); Ben Cosgrove, Shepshed (GB)

(21) Appl. No.: 15/804,705

(22) Filed: Nov. 6, 2017

(51) Int. Cl. B60L 11/18; H05K 5/02; H01M 2/10; B60K 1/04

(52) U.S. Cl. CPC B60L 11/1877; H05K 5/0239; H01M 2/1083; G05D 1/0011; H01M 2220/20; B60K 2001/0438; B60Y 2200/91; B60K 1/04

(57) ABSTRACT

An implementation of a battery cradle includes a tray, a first side frame attached to a first side of the tray, and a second side frame attached to a second side of the frame. The first side frame and the second side frame face each other and are substantially parallel to one another. Both the first side frame and the second side frame include a plurality of generally circular recesses, in which each recess on the first side frame is opposite to and aligned with a recess on the second side frame. Each pair of aligned recesses accommodates a generally cylindrical battery. According to various implementations, the tray includes (i) a plurality of depressions, each of which is aligned with a pair of aligned recesses and (ii) a plurality of slats configured to accommodate a prism-shaped battery pack.

### TECHNICAL FIELD

The present disclosure is related generally to battery holders and, more particularly, to a battery cradle and battery cradle assembly.

### BACKGROUND

There are many types of devices that operate on portable battery power. For example, many consumer-level remotely-controlled vehicles (e.g., aerial drones and wheeled vehicles) are required to carry one or more batteries. The consumer is generally not, however, allowed to pick which type of battery to use (e.g., single cell, multiple cell packs) but is limited to using one type of battery, which is specified by the manufacturer.

### DRAWINGS

While the appended claims set forth the features of the present techniques with particularity, these techniques, together with their objects and advantages, may be best understood from the following detailed description taken in conjunction with the accompanying drawings of which:

FIG. 1A is a top perspective view of a battery cradle configured according to an embodiment.

FIG. 1B is a bottom perspective view of the battery cradle of FIG. 1A.

FIG. 1C is an elevated side view of the battery cradle of FIG. 1A.

FIG. 1D is a top view of a variation of the battery cradle of FIG. 1A, FIG. 1B, and FIG. 1C.

FIG. 2A is a perspective view of a battery cradle assembly configured according to an embodiment, with the door in a fully open position.

FIG. 2B is a perspective view of the battery cradle assembly of FIG. 2A, with the door in a partially open position.

FIG. 2C is a perspective view of the battery cradle assembly of FIG. 2A, with the door in a fully closed position.

FIG. 3A is a cutaway view of a battery cradle assembly similar to those of FIGS. 2A-2C, showing a battery cradle inserted within a compartment, according to an embodiment.

FIG. 3B is an enlarged view of area A of FIG. 3A.

FIG. 4A is a perspective view of a model vehicle chassis that includes a battery cradle assembly according to an embodiment, with the battery cradle holding two partially-inserted lithium-ion cells in a weight-rearward configuration.

FIG. 4B is a perspective view of the model vehicle chassis of FIG. 4A, with two partially-inserted lithium-ion cells in a weight-centralized configuration.

FIG. 4C is a perspective view of the model vehicle chassis of FIG. 4A, with two partially-inserted lithium-ion cells in a weight-forward configuration.

FIG. 4D is a perspective view of the model vehicle chassis of FIG. 4A, with four partially-inserted lithium-ion cells in a weight-rearward configuration.

FIG. 4E is a perspective view of the model vehicle chassis of FIG. 4A, with four partially-inserted lithium-ion cells in a weight-forward configuration.

FIG. 4F is a perspective view of the model vehicle chassis of FIG. 4A, with four partially-inserted lithium-ion cells in a weight-centralized configuration.

FIG. 4G is a perspective view of the model vehicle chassis of FIG. 4A, with six partially-inserted lithium-ion cells.

FIG. 5A is a perspective view of a model vehicle chassis that includes a battery cradle assembly according to an embodiment, with the battery cradle holding a prism-shaped nickel-metal hydride battery that is partially inserted.

FIG. 5B is a perspective view of the model vehicle chassis of FIG. 5A, with the battery cradle holding a prism-shaped lithium polymer battery that is partially inserted.

FIG. 6A is a perspective view of a model vehicle chassis in which battery cables originating from a battery in an interior compartment are coupled to a connector on the exterior of the chassis, according to an embodiment.

FIG. 6B is a perspective view of a model vehicle chassis in which battery cables originating from a battery in an interior compartment pass through a hole in the chassis, according to an embodiment.

FIG. 6C is a perspective view of a model vehicle chassis in which battery cables originating from a battery in an interior compartment pass through a gap between the front of the door and the chassis, according to an embodiment.

FIG. 6D is a perspective view of a model vehicle chassis in which battery cables originating from a battery in an interior compartment pass through a gap between the rear of the door and the chassis, according to an embodiment.

FIGS. 7A-7E are circuit diagrams showing possible sets of electrical connections for cylindrical batteries for the assembly described herein, according to various embodiments.

### DESCRIPTION

The present disclosure is generally directed to a battery cradle and battery cradle assembly. According to various embodiments, the battery cradle includes a tray, a first side frame attached to a first side of the tray, and a second side frame attached to a second side of the frame (offering support in three planes). The first side frame and the second side frame face each other and are substantially parallel to one another. Both the first side frame and the second side frame include a plurality of generally circular recesses, in which each recess on the first side frame is opposite to and aligned with a recess on the second side frame. Each pair of aligned recesses accommodates a generally cylindrical battery. According to various embodiments, the tray includes (i) a plurality of depressions, each of which is aligned with a pair of aligned recesses and (ii) a plurality of slats configured to accommodate a prism-shaped battery package. Each slat has a generally planar surface and is positioned at an offset with respect to the aligned recesses.

In an embodiment, a battery cradle assembly includes: a compartment having an inner surface and an opening, a plurality of sockets on the inner surface at the opening, and a battery cradle. The battery cradle in this embodiment includes: a tray comprising a plurality of slats configured to support a prism-shaped battery package and a plurality of depressions interspersed among the plurality of slats and configured to support two or more cylindrically-shaped batteries; a first side frame attached to a first side of the tray; a second side frame attached to a second side of the tray, wherein the first side frame and the second side frame are substantially parallel with one another; and a plurality of protrusions extending from the first side frame, wherein at least some of the plurality of protrusions are configured to interlock with the plurality of sockets.

According to various embodiments, a single battery cradle is provided that, without new or additional parts or rewiring, can accommodate individual cylindrical cells (so-called “loose cells” or cells not soldered or welded together into a pre-built battery pack, e.g., 18650 type lithium-ion (“Li-Ion”) cells), as well as hobby standard pre-built packs (e.g., lithium polymer (“LiPo”) or nickel metal hydride (“NiMh”) multi-cell packs). This makes the cradle easy to use and allows users to choose their preferred battery type. Example use cases for the cradle include hobby-level remotely-controlled vehicles (e.g., wheeled vehicles that can go faster than 10 miles per hour).

In various embodiments, the wiring for different battery configurations is embedded in a vehicle chassis in which the cradle is used. Such a configuration accommodates future developments, such as vehicles having increased power, range, and/or speed (which may require more Li-Ion batteries. Moreover, physically larger (higher power and greater capacity) LiPo and NiMh batteries could also be used in physically larger cradle-and-chassis configurations.

In an embodiment, the dimensions of the recesses of the cradle (in terms of spacing between the two recesses of each pair and in terms of the circumference of each individual recess) are such that each pair can accommodate a standard cylindrical battery, such as a 18650 Li-Ion cell, while the overall dimensions of the cradle are such that it can accommodate a NiMh cell pack or a 2S LiPo pack.

According to an embodiment, the dovetails of the cradle ‘key-in’ to a chassis structure (e.g., of a remotely-controlled model vehicle (e.g., wheeled or airplane)) with, for example, twenty dovetails (creating twenty dovetail joints), thereby giving strength along the length, width, and height of the chassis.

In an embodiment, the cradle accommodates up to six Li-Ion (18650) batteries, one NiMh pack (with six cells), or one LiPo (2S) pack, and is made of a single piece of plastic, such that the cradle is strong in three axes (length, width, and height).

According to an embodiment, the cradle assembly is pre-wired for additional pairs of cells to be added easily (e.g., increasing the number from two to four and from four to six) to increase total battery capacity for additional speed and run-time (e.g., of a remotely-controlled model vehicle).

In an embodiment, when the cradle assembly deployed in a chassis, a standard T-connector is fitted to the chassis for easy and consistent battery connectivity.

According to an embodiment, the batteries accommodated by the cradle are power cells, in that they provide motive power (e.g., to a remotely-controlled model vehicle) as opposed to merely providing power for a radio receiver or other ancillary functions.

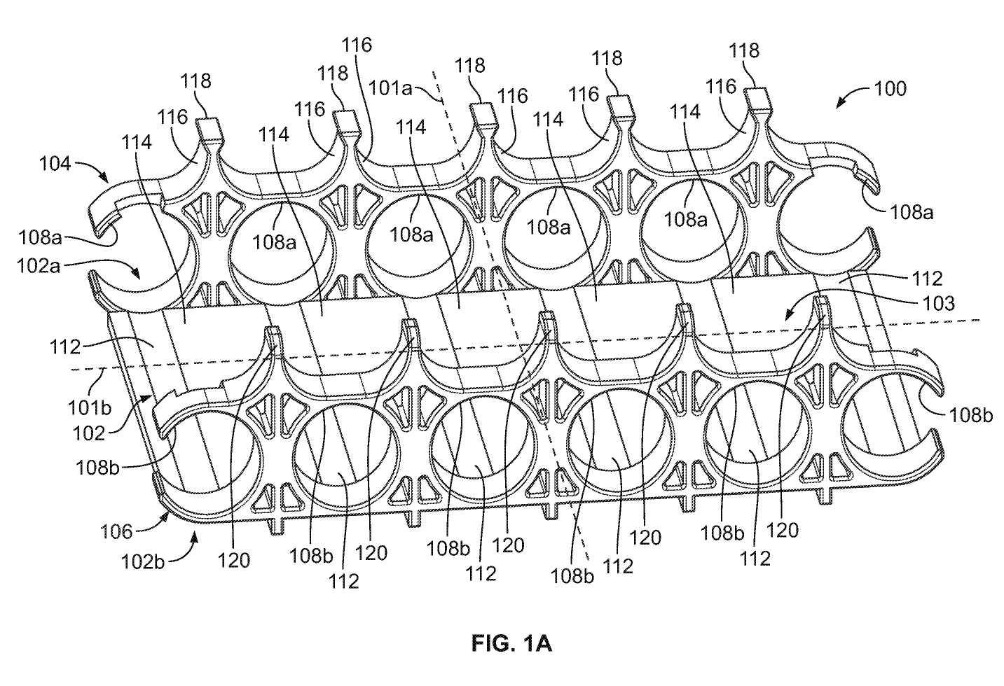

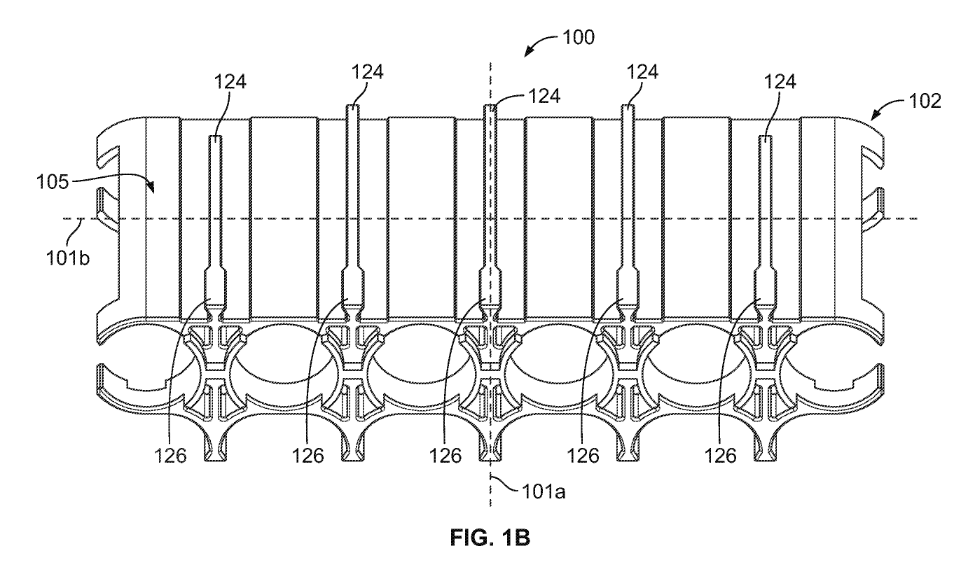

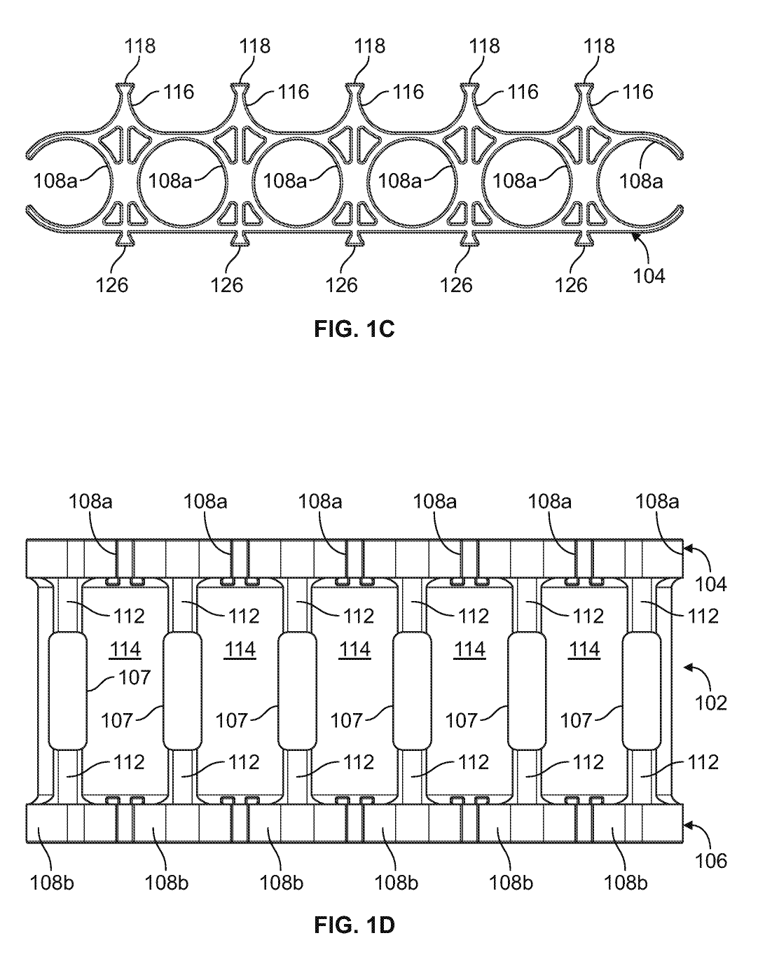

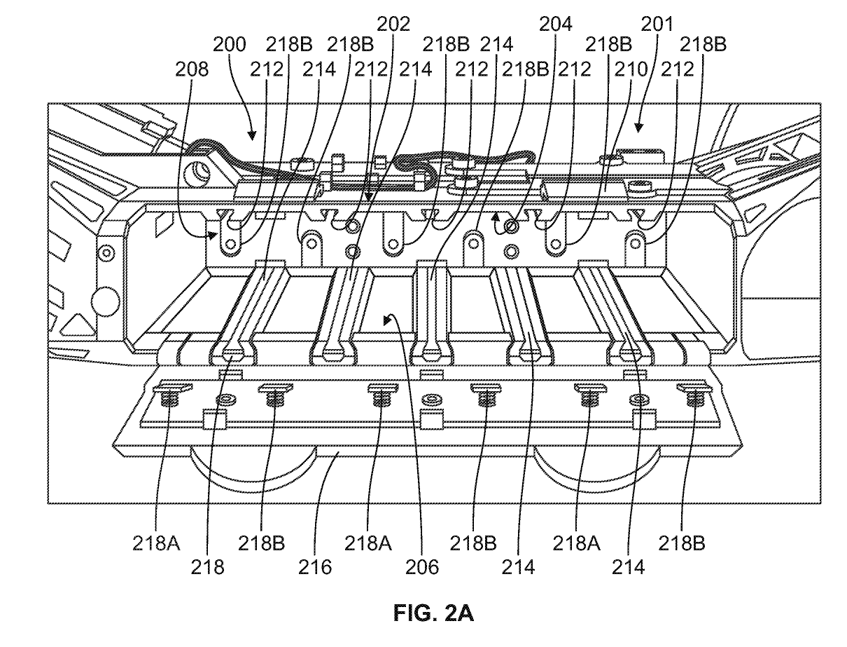

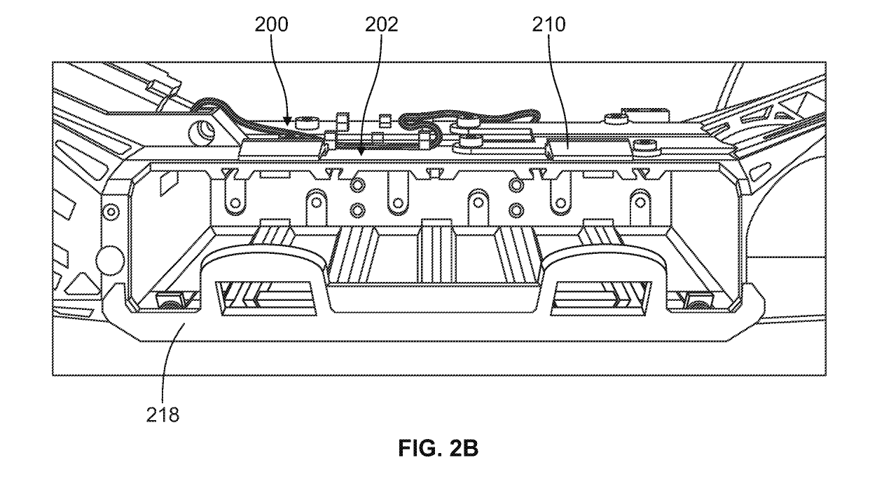

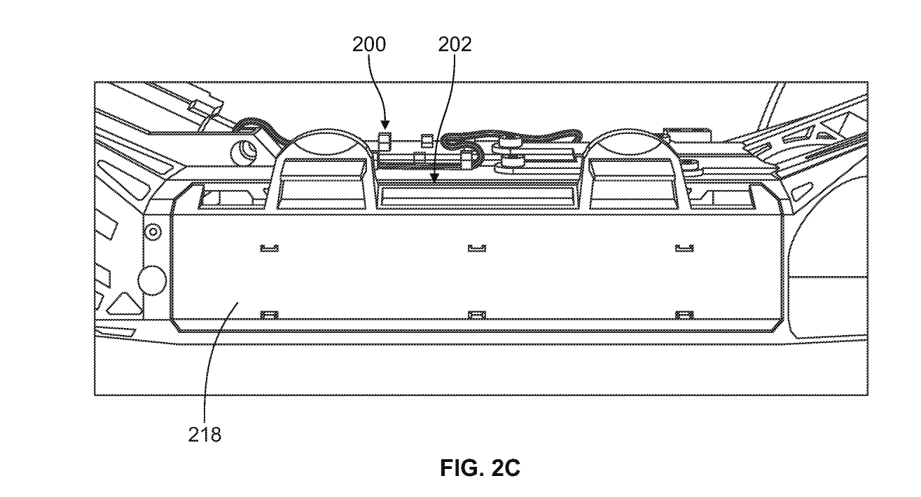

Turning to FIG. 1A and FIG. 1B, a battery cradle configured according to an embodiment is shown. The battery cradle, generally labeled 100, has a first axis 101a and a second axis 101b. The cradle 100 includes a tray 102 having a first side 102a and a second side 102b. The battery cradle also includes a first side frame 104 on the first side 102a, and a second side frame 106 on the second side 102b. In an embodiment, the tray 102 and side frames 104 and 106 are part of a single piece of material (such as molded plastic). In other embodiments, the first side frame 104 and the second side frame 106 are separate pieces that are fastened to the tray 102. The first side frame and second side frame each have generally circular recesses that are configured to receive generally cylindrical batteries (such as the cylindrical batteries shown in FIGS. 2A-2G). In the embodiment of FIGS. 1A and 1B, the recesses are implemented as circular hole pairs, each pair including a first circular hole 108a and a second circular hole 108b, which are aligned along the width (parallel to the first axis 101a) of the cradle 100.

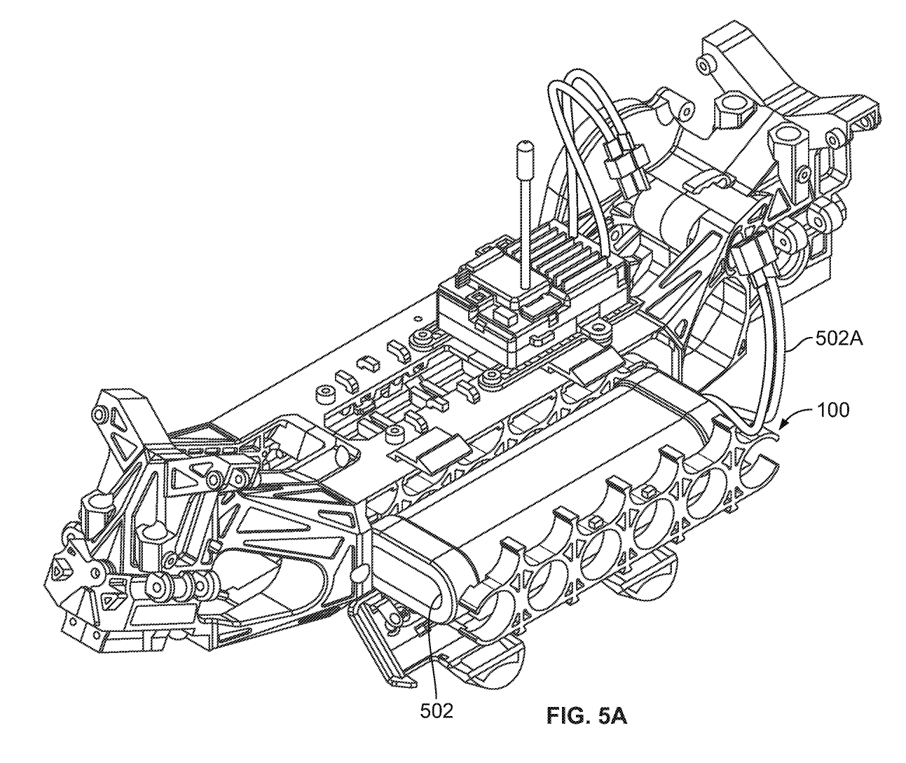

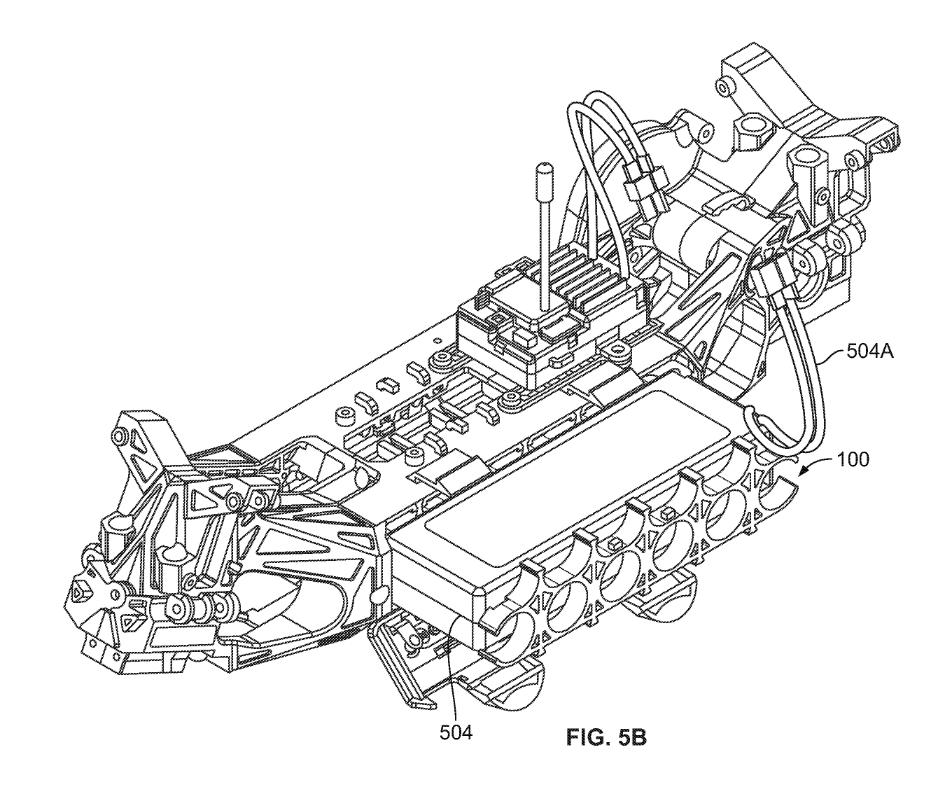

According to an embodiment, the tray 102 has a first surface 103 (FIG. 1A) and a second surface 105 (FIG. 1B). The first surface 103 and the second surface 105 are continuous in the embodiment shown in FIG. 1A and FIG. 1B but may include gaps. The first surface 103 has a series of depressions 112, each of which is aligned with a pair of the recesses (e.g., a pair of holes 108a and 108b). The first surface also has a series of slats 114 configured to accommodate a prism-shaped battery package (such as the battery package 502 shown in FIG. 5A or the battery package 504 shown in FIG. 5B). Each slat 114 has a generally planar surface (to accommodate a prism-shaped battery package) and is positioned at an offset (laterally along the width of the cradle 100) with respect to the aligned recess pairs 108a and 108b.

In some embodiments, such as that shown in FIG. 1D, each depression 112 has a gap 107 in the material that makes up the depression 112. In other words, each gap 107 defines a passage from the first surface 103 to the second surface 105.

In an embodiment, the first side frame 104 (FIGS. 1A and 1C) includes a first series of protrusions 116, each of which is aligned with a slat 114. At the distal end (i.e., distal relative to the first side frame 104) of each protrusion 116 is a dovetail 118. The second side frame 106 includes a series of protrusions 120 that do not have dovetails.

Referring again to FIG. 1B, formed on the second surface 105 is a series of protrusions 124, some of which run the entire width of the tray 102. Each of the protrusions 124 has a dovetail 126 on the distal end (i.e., distal from the surface 105). The dovetail 126 may or may not run the entire length of the protrusion 124.

Turning to FIGS. 2A-2C, a battery cradle assembly configured according to an embodiment will now be described in the context of a model wheeled vehicle. The battery cradle assembly, generally labeled 201, holds one of three types of batteries and, during operation of the vehicle, is housed in a chassis 200 of the vehicle. The assembly 201 includes a compartment 202 having an upper inner surface 204, a lower inner surface 206, a rear surface 208, and an opening 210. A first series of sockets 212 is formed on the upper inner surface 204 and a second series of sockets 214 is formed on the lower inner surface 206. The assembly 201 further includes a door 216 attached to the chassis 200 by a hinge 218 at the opening 210. When the door 216 is closed (as shown in FIG. 2C) the door 216 covers the opening 208. Attached to the door 216 are electrical contacts 218a, each of which makes an electrical connection to a terminal of a cylindrical battery (if cylindrical batteries are being used). Attached to the rear surface 208 are electrical contacts 218b, each of which makes an electrical connection to a terminal of a cylindrical battery. The electrical contacts 218a and 218b operate in pairs, so that, for each cylindrical battery used, one of the electrical contacts 218a on the door 216 (when the door 216 is closed) makes an electrical connection with one of the terminals of the battery while one of the electrical contacts 218b on the rear surface 208 makes an electrical connection with the other terminal of the battery.

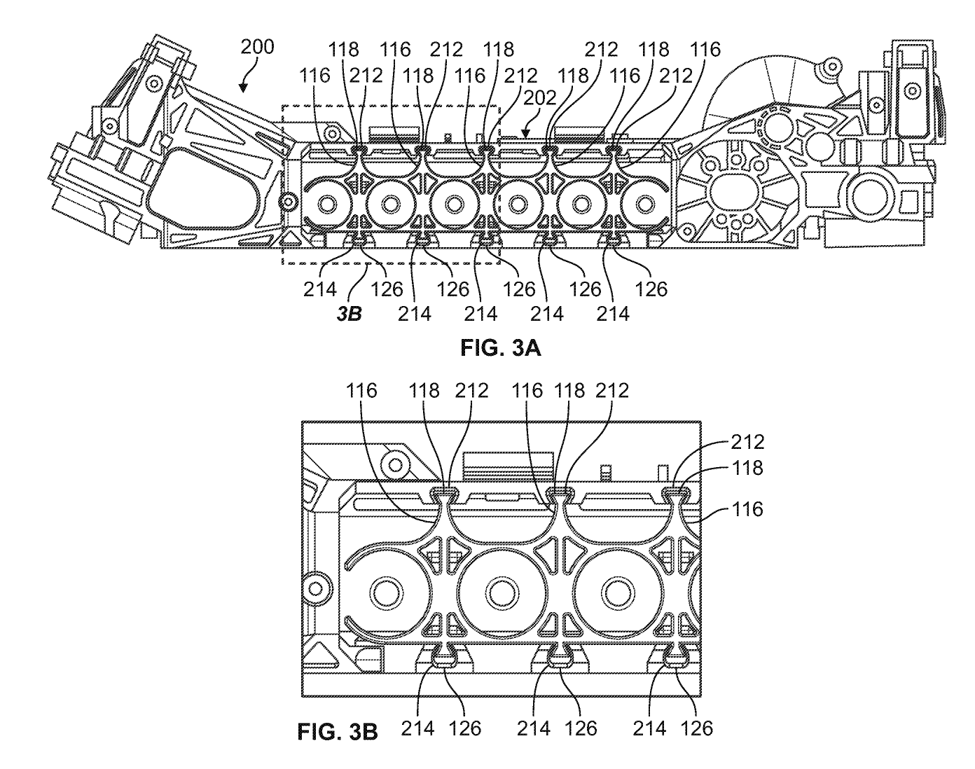

Turning to FIGS. 3A and 3B, in an embodiment, the cradle 100 slides into the compartment 202 via engagement between the first series of protrusions 116 (of the first side frame 104) and the first series of sockets 212, and via engagement between the protrusions 124 on the bottom (the second surface 105) of the tray 200 and the second series of sockets 214. In particular, each dovetail 118 engages with a similarly-shaped hole of a corresponding socket 212 of the first series of sockets and each dovetail 126 engages with a similarly-shaped hole of a corresponding socket 214 of the second series of sockets. Each socket-dovetail combination forms a dovetail joint.

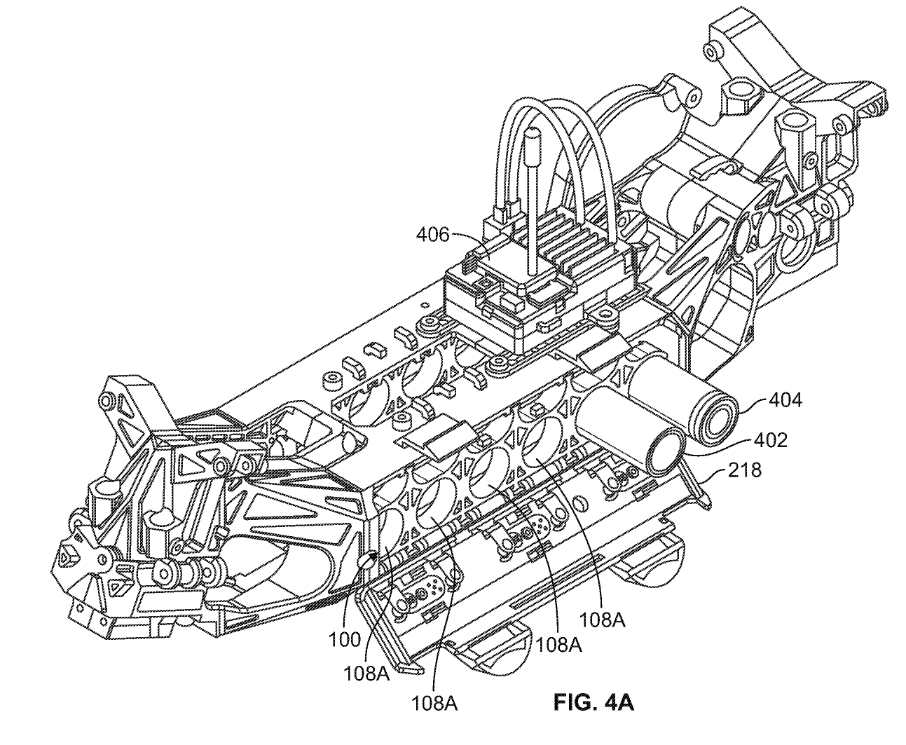

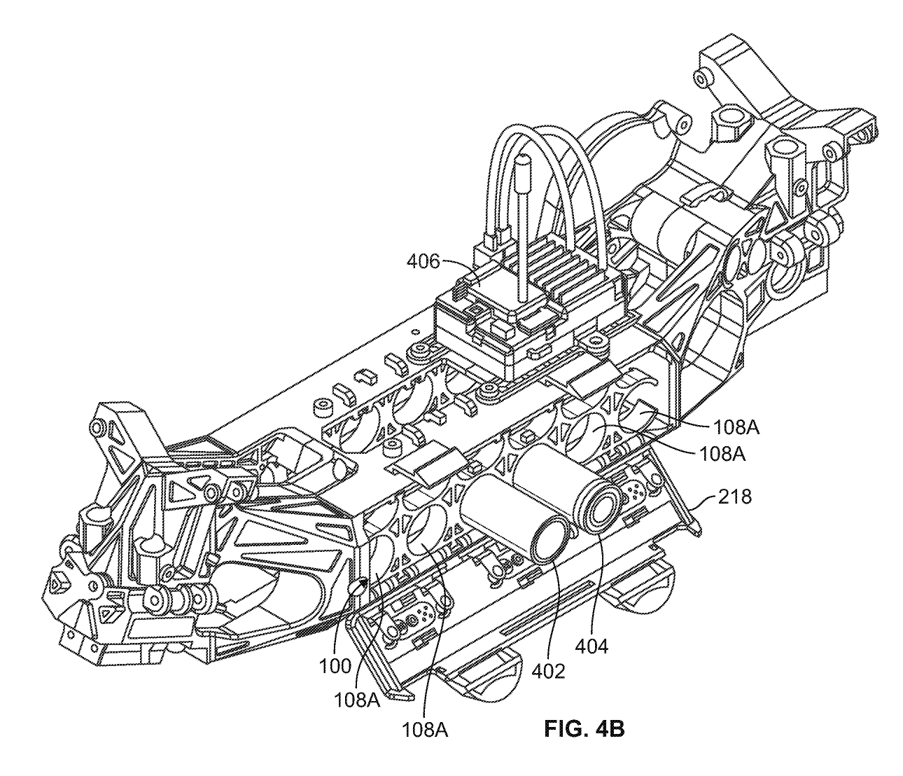

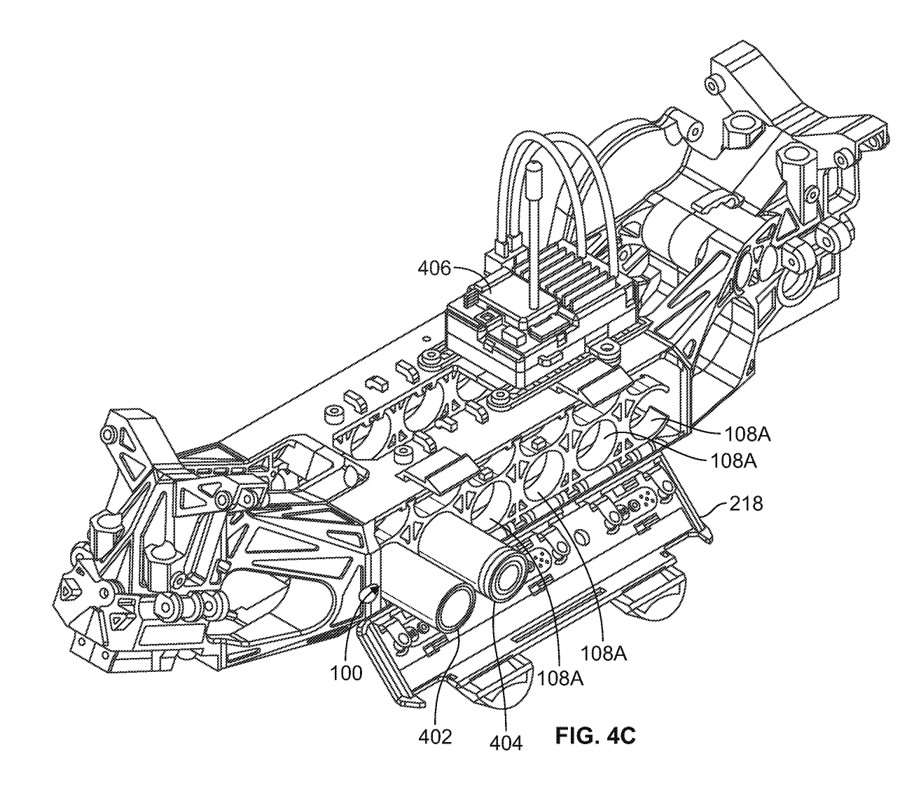

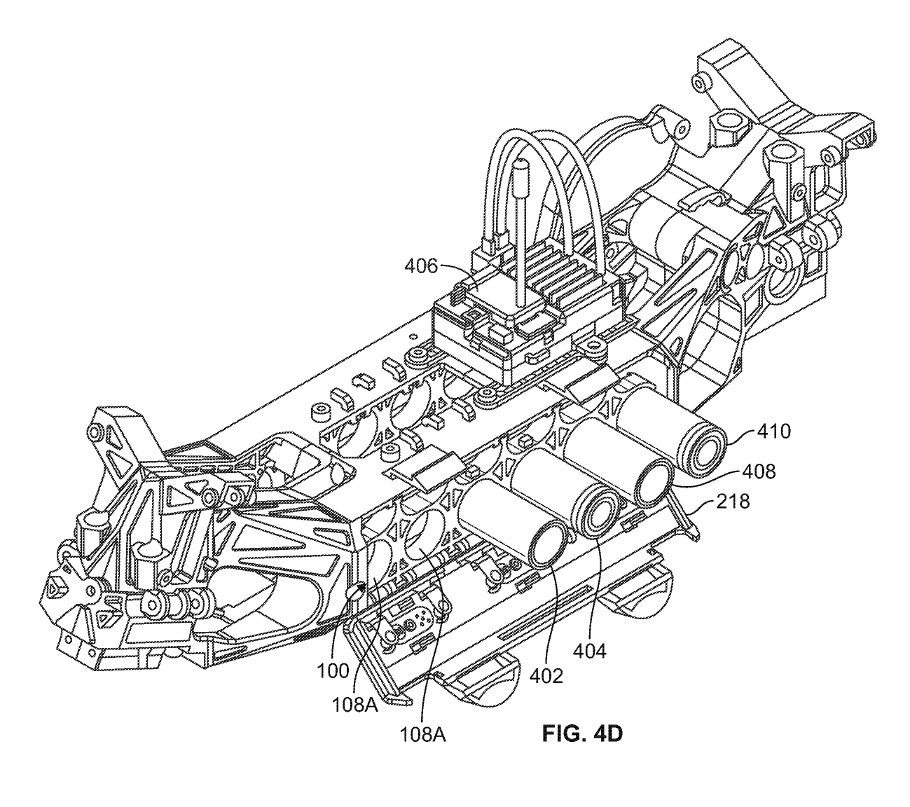

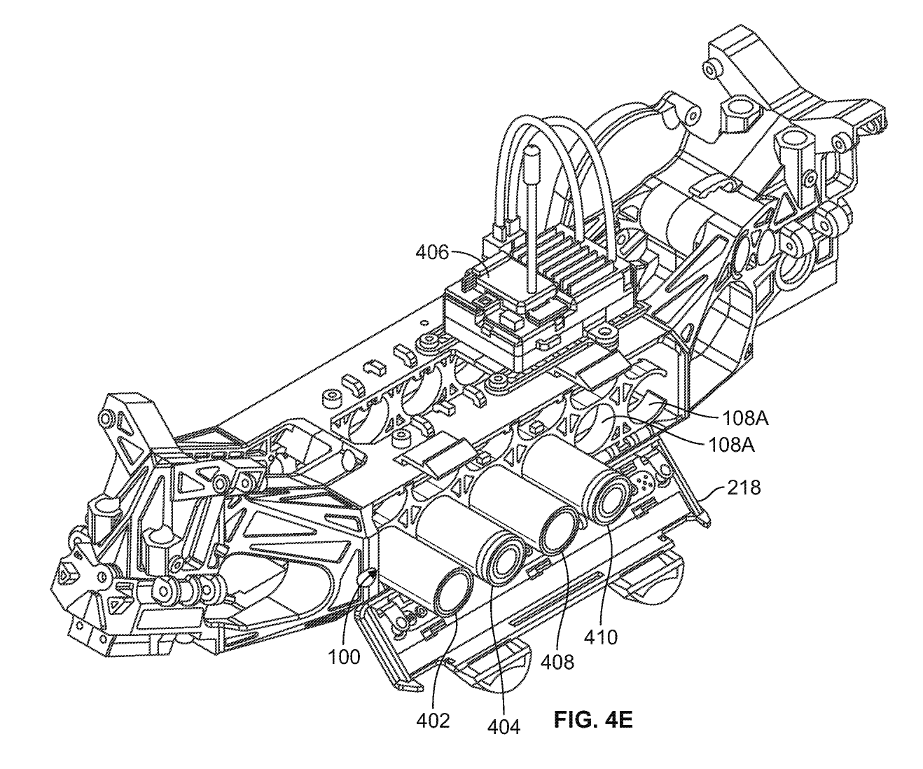

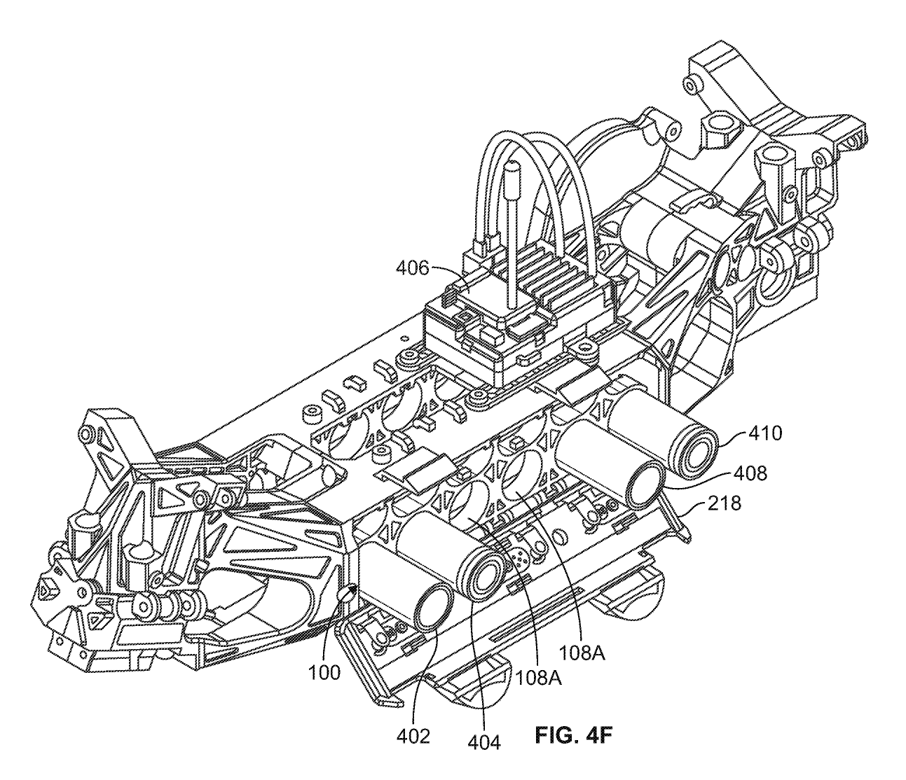

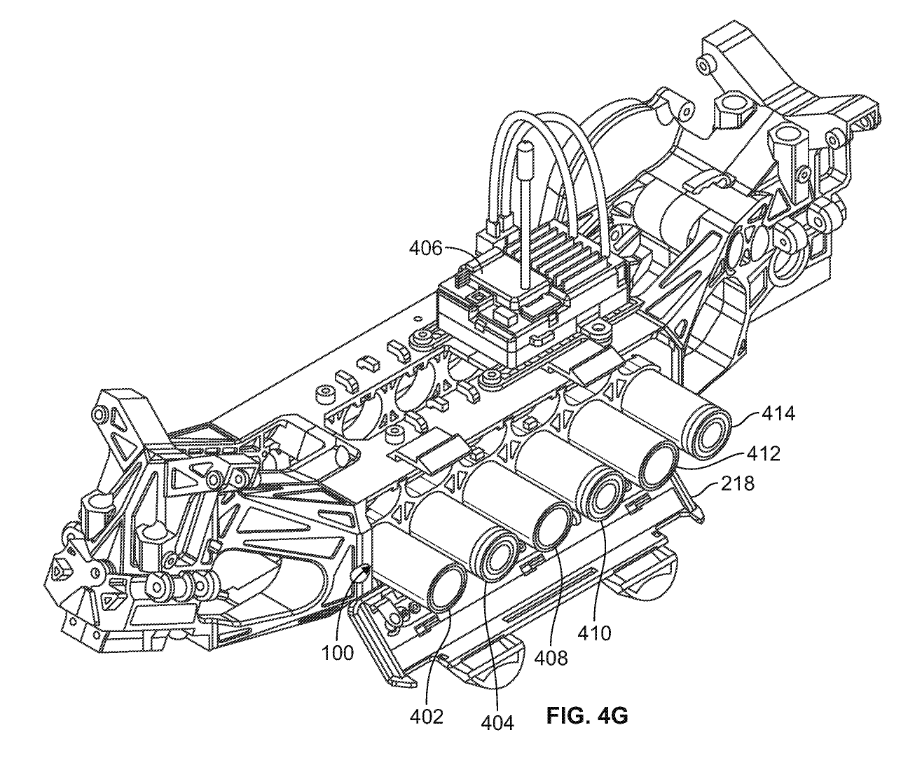

According to an embodiment, if cylindrical batteries are used in the battery cradle assembly 201, they are connected in pairs, such that each battery of a pair is electrically connected in series with the other battery of the pair, but the pair as a whole is electrically connected in parallel with the rest of the circuit, as shown in FIG. 4A, FIG. 4B, and FIG. 4C in which a first battery 402 is electrically connected in series with a second battery 404, while the two batteries are electrically connected in parallel with a circuit that includes a motor 406 (to which the batteries supply power). If further pairs of batteries are used, such as the batteries 408 and 410 (FIGS. 4C-4G), and 412 and 414 (FIG. 4G), then each pair is electrically connected in parallel with the other pairs (though in series within its pair). In one implementation, the cylindrical batteries are 18650 lithium ion batteries.

As previously discussed, the various embodiments of the battery cradle and battery cradle assembly accommodate cylindrically-shaped batteries as well as a prism-shaped battery. The tray of the cradle has a series of recesses and depressions to accommodate the cylindrically-shaped batteries (e.g., along the width of the cradle 100—parallel to the first axis 101a) as well as planar surfaces to accommodate the prism-shaped battery (e.g., along the length of the cradle—parallel to the second axis 101b). When a prism-shaped battery is used, an elongated surface of the prism-shaped battery sits on the planar surfaces of the tray (e.g., on the slats 114) and on top of (e.g., without making contact with) the depressions (e.g., the depressions 112). The first side frame and the second side frame each hold the prism-shaped battery in place, with the recesses serving no role with respect to the prism-shaped battery). This can be seen in FIG. 5A, in which the cradle 100 is shown holding a 2S LiPo battery 502, and in FIG. 5B, in which the cradle 100 is shown holding a six-cell NiMh battery 504. Each of the batteries 502 and 504 has respective cables 502a and 504a, which contain positive and negative electrical leads from the battery.

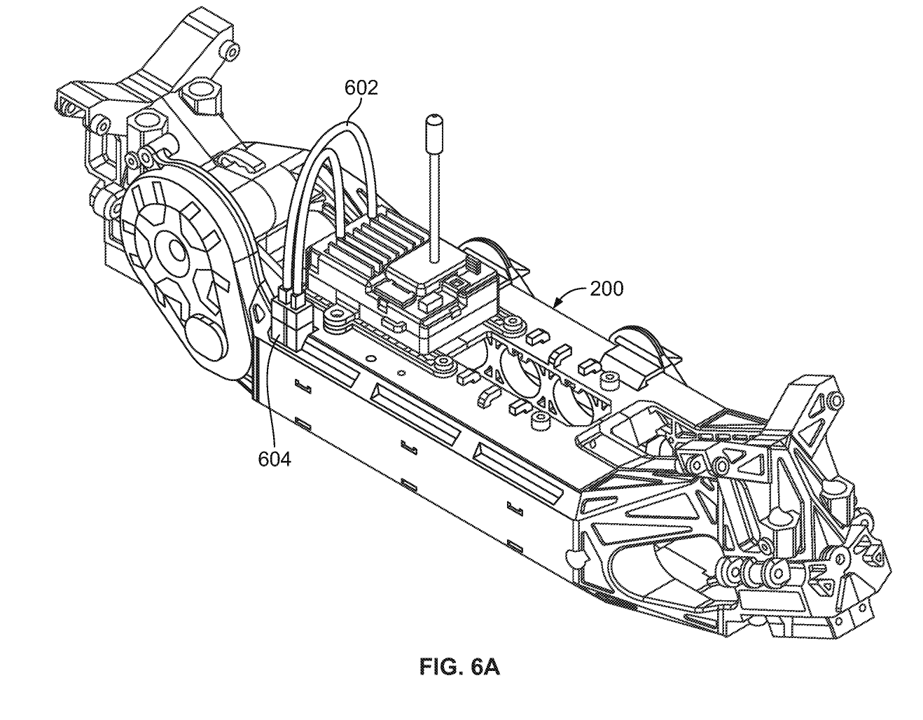

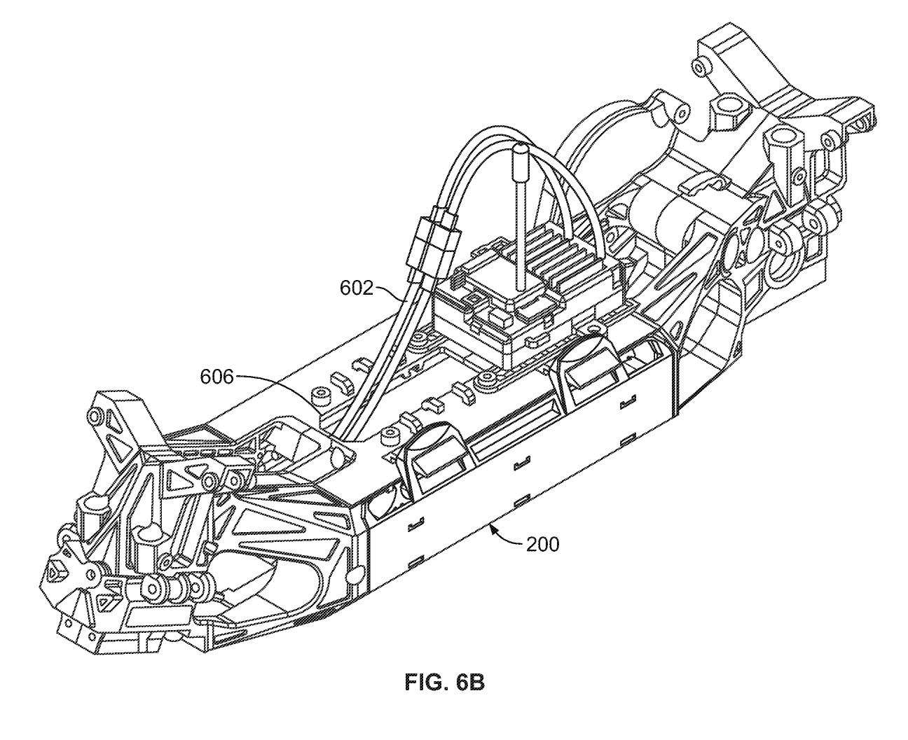

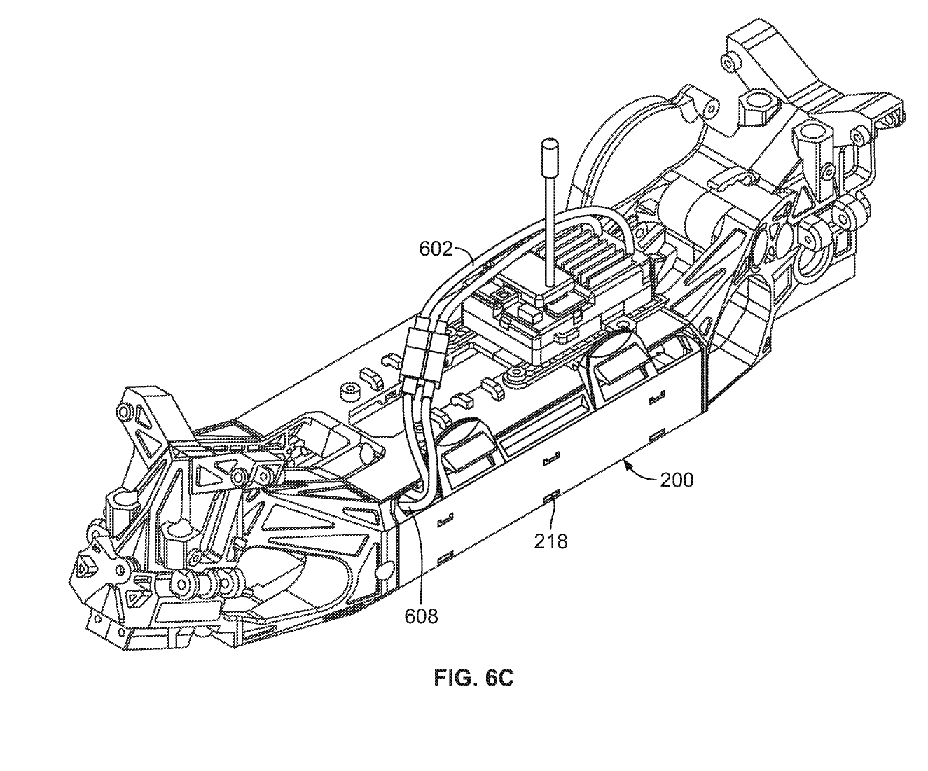

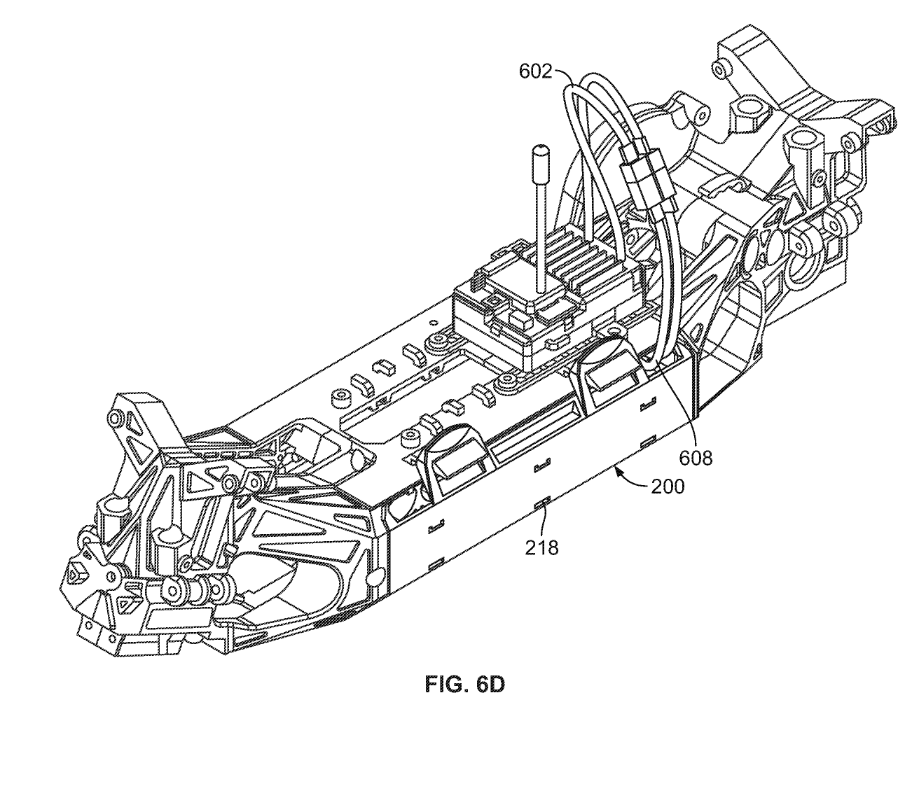

According to an embodiment, if a battery having a cable connector (such as a LiPo battery or a NiMh battery) is used, the connector of the battery plugs in to a plug on the structure that surrounds the compartment in which the battery (within its cradle) is located. For example, FIG. 6A shows the cable 602 from the battery as passing through a hole (not shown in FIG. 6A) in the chassis 200 and connecting to a connector 604. FIG. 6B shows the cable 602 from the battery coming up through a hole 606 in the top of the chassis 200. FIG. 6C shows the cable 602 from the battery coming up through a gap 608 in the between the door 216 and the chassis 200 at the front of the door 216. FIG. 6D shows the cable 602 from the battery coming out through a gap 608 in the between the door 216 and the chassis 200 at the rear of the door 216.

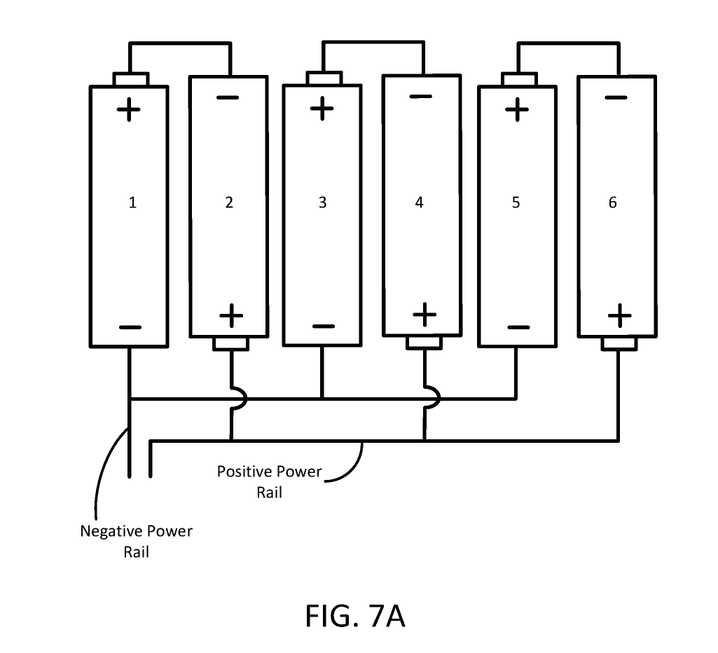

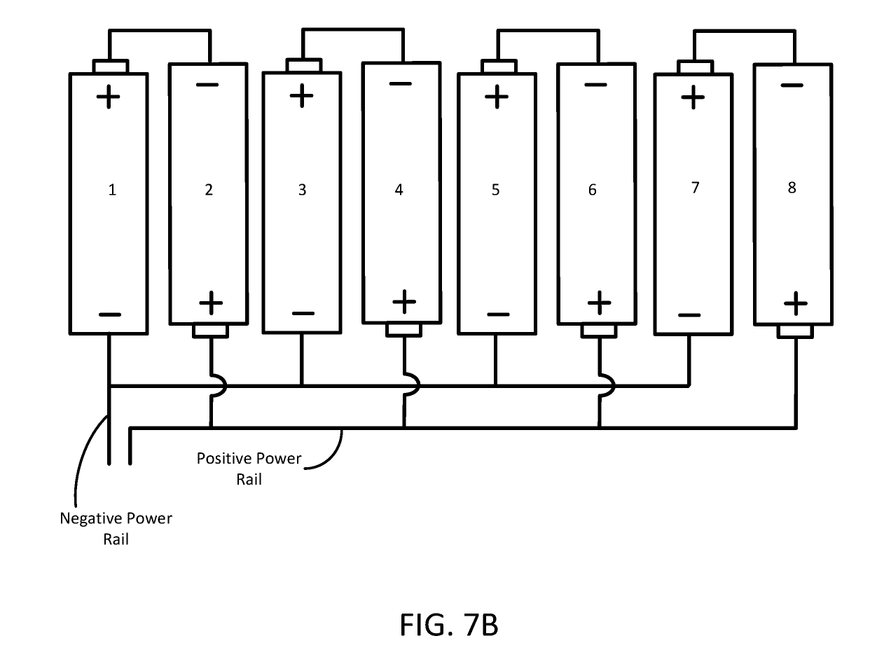

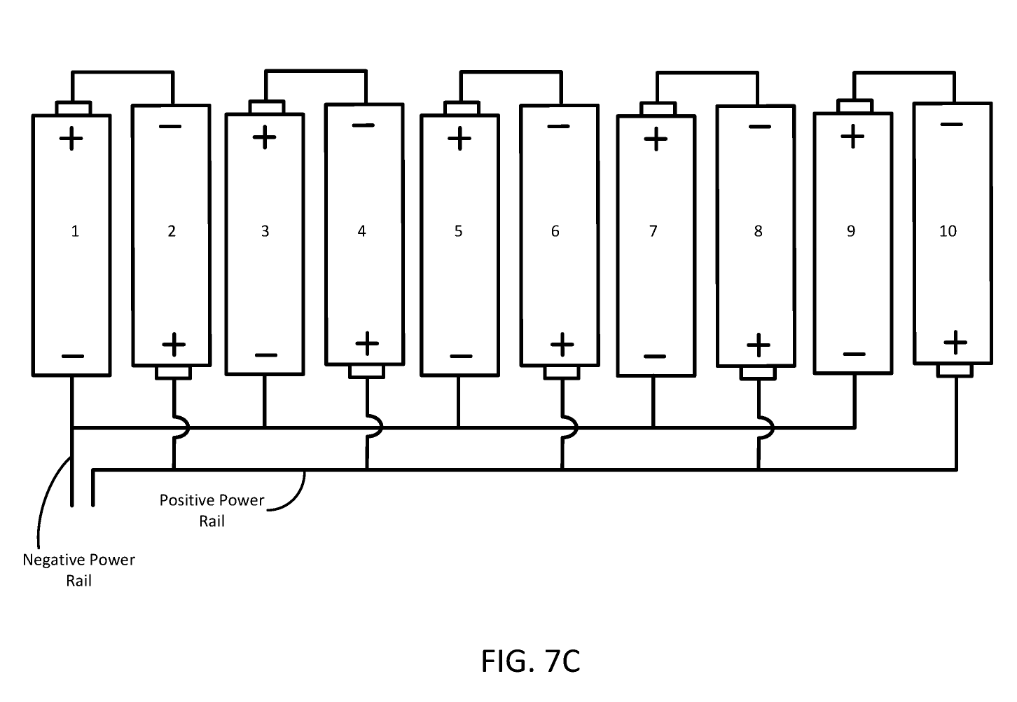

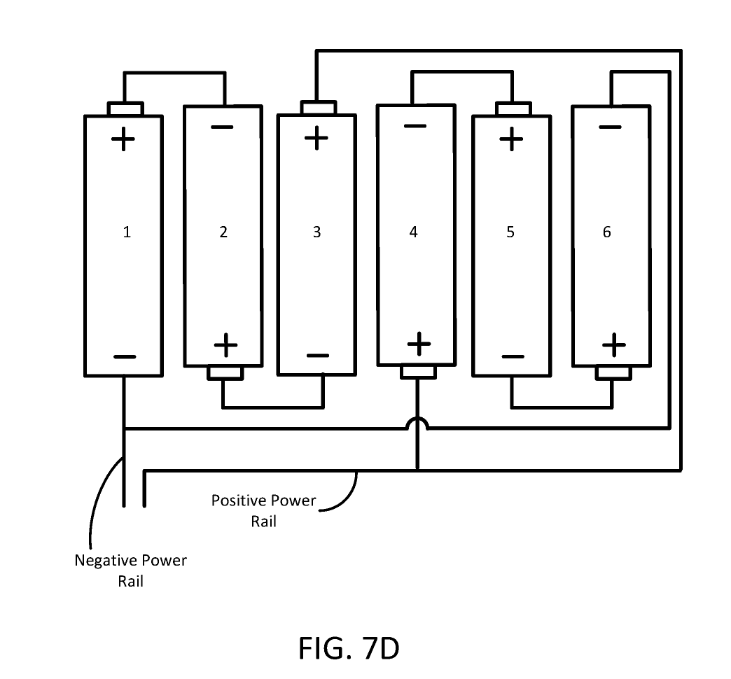

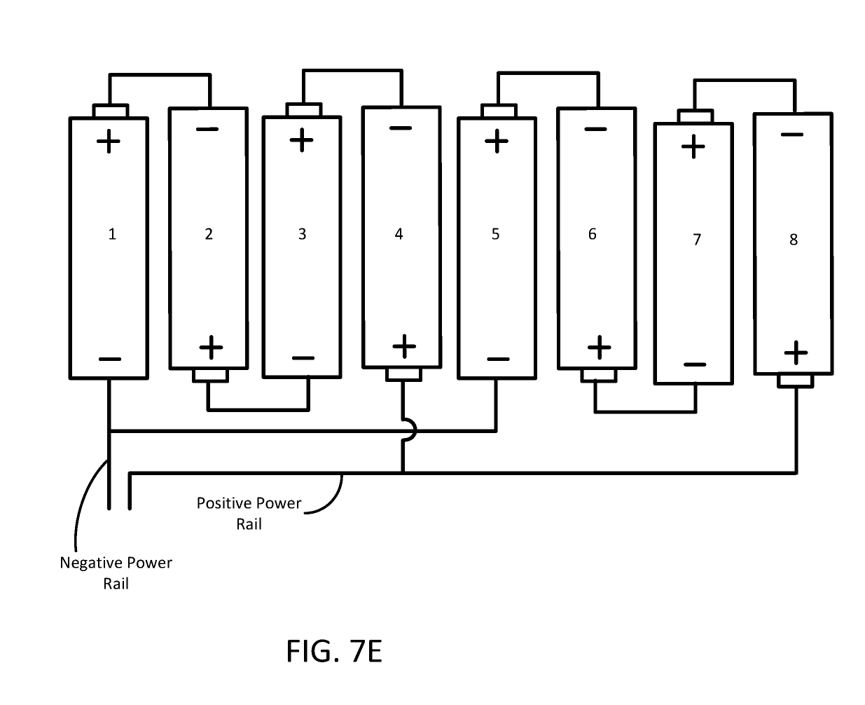

FIG. 7A is a circuit diagram showing one possible set of electrical connections for cylindrical batteries for the assembly described herein, according to an embodiment. The cylindrical batteries include six batteries (e.g., 18650 Li-Ion batteries) labelled 1 through 6, which are connected to a negative power rail and a positive power rail. Possible battery arrangements for this set of electrical connections (with ‘P’ indicating a parallel connection and ‘S’ indicating a serial connection) include (a) 2S 1P cell configurations 1+2 or 3+4 or 5+6, (b) 2S 2P cell configurations 1+2+3+4 or 1+2+5+6 or 3+4+5+6, and (c) 2S 3P cell configurations 1+2+3+4+5+6.

FIG. 7B is a circuit diagram showing another possible set of electrical connections for cylindrical batteries for the assembly described herein, according to an embodiment. The cylindrical batteries include eight batteries labelled 1 through 8, which are connected to a negative power rail and a positive power rail. Possible battery arrangements for this set of electrical connections include (a) 2S 1P cell configurations 1+2 or 3+4 or 5+6 or 7+8, (b) 2S 2P cell configurations 1+2+3+4 or 1+2+5+6 or 1+2+7+8 or 3+4+5+6 or 3+4+7+8 or 5+6+7+8, (c) 2S 3P cell configurations 1+2+3+4+5+6 or 1+2+3+4+7+8 or 1+2+5+6+7+8 or 3+4+5+6+7+8, and (d) 2S 4P cell configurations 1+2+3+4+5+6+7+8.

FIG. 7C is a circuit diagram showing another possible set of electrical connections for cylindrical batteries for the assembly described herein, according to an embodiment. The cylindrical batteries include ten batteries labelled 1 through 10, which are connected to a negative power rail and a positive power rail. Possible battery arrangements for this set of electrical connections include (a) 2S 1P cell configurations 1+2 or 3+4 or 5+6 or 7+8 or 9+10, (b) 2S 2P cell configurations 1+2+3+4 or 1+2+5+6 or 1+2+7+8 or 1+2+9+10 or 3+4+5+6 or 3+4+7+8 or 3+4+9+10 or 5+6+7+8 or 5+6+9+10 or 7+8+9+10, (c) 2S 3P cell configurations 1+2+3+4+5+6 or 1+2+3+4+7+8 or 1+2+3+4+9+10 or 1+2+5+6+7+8 or 1+2+5+6+7+10 or 1+2+7+8+9+10 or 3+4+5+6+7+8 or 3+4+5+6+9+10 or 3+4+7+8+9+10 or 5+6+7+8+9+10, (d) 2S 4P cell configurations 1+2+3+4+5+6+7+8 or 1+2+3+4+5+6+9+10 or 1+2+5+6+7+8+9+10 or 1+2+3+4+7+8+9+10 or 3+4+5+6+7+8+9+10, and (e) 2S 5P cell configuration 1+2+3+4+5+6+7+8+9+10.

FIG. 7D is a circuit diagram showing another possible set of electrical connections for cylindrical batteries for the assembly described herein, according to an embodiment. The cylindrical batteries include six batteries labelled 1 through 6, which are connected to a negative power rail and a positive power rail. Possible battery arrangements for this set of electrical connections include (a) 3S 1P cell configurations 1+2+3 or 4+5+6 and (b) 3S 2P cell configuration 1+2+3+4+5+6.

FIG. 7E is a circuit diagram showing another possible set of electrical connections for cylindrical batteries for the assembly described herein, according to an embodiment. The cylindrical batteries include eight batteries labelled 1 through 8, which are connected to a negative power rail and a positive power rail. Possible battery arrangements for this set of electrical connections include (a) 4S 1P cell configurations 1+2+3+4 or 5+6+7+8 and (b) 4S 2P cell configuration 1+2+3+4+5+6+7+8.

It should be understood that the exemplary embodiments described herein should be considered in a descriptive sense only and not for purposes of limitation. Descriptions of features or aspects within each embodiment should typically be considered as available for other similar features or aspects in other embodiments. It will be understood by those of ordinary skill in the art that various changes in form and details may be made therein without departing from their spirit and scope of as defined by the following claims.

What is claimed is:

1. A battery cradle comprising:
a tray having a first axis and a second axis, wherein the first axis is shorter than the second axis, the tray comprising one or more planar surfaces configured to accommodate a prism-shaped battery oriented along the second axis;
a first frame connected to a first side of the tray, the first frame comprising a first set of recesses;
a second frame connected to a second side of the tray, the second frame comprising a second set of recesses;
wherein the first and second sets of recesses are configured to hold a plurality of cylindrical batteries therebetween so that each of the plurality of batteries is oriented generally parallel to or along the first axis.

2. The battery cradle of claim 1, wherein the tray further comprises a plurality of depressions oriented generally parallel to the first axis, wherein each depression is configured to accommodate a cylindrical battery of the plurality of cylindrical batteries.

3. The battery cradle of claim 2, wherein
each of the first set of recesses forms a pair with one of the second set of recesses so as to constitute a plurality of pairs of recesses,
each of the plurality of depressions is aligned with a respective one of the plurality of recess pairs along the first axis.

4. The battery cradle of claim 3, wherein the recesses of at least one of the plurality of pairs are circular holes.

5. The battery cradle of claim 1, wherein the tray further comprises a plurality of slats, each planar surface being formed on a respective slat of the plurality.

6. The battery cradle of claim 5, wherein
each of the first set of recesses forms a pair with one of the second set of recesses so as to constitute a plurality of pairs of recesses,
each of the plurality of slats is offset along the second axis with respect to a pair of recesses of the plurality of recesses.

7. The battery cradle of claim 5, wherein the tray has a plurality of holes therethrough, each hole being defined between adjacent slats of the plurality of slats.

8. The battery cradle of claim 1, wherein the first frame further comprises a plurality of protrusions, wherein each protrusion of the plurality is configured to interlock with a similarly-shaped socket.

9. The battery cradle of claim 8, wherein each protrusion of the plurality comprises a dovetail at the distal end of the protrusion, wherein the dovetail of the protrusion is configured to interlock with a similarly-shaped dovetail socket to form a dovetail joint.

10. The battery cradle of claim 1, wherein the tray, the first frame, and the second frame are part of a single unitary body.

11. A battery cradle assembly comprising:
a compartment comprising an inner surface;
a plurality of sockets on the inner surface at an opening of the compartment; and
a battery cradle comprising
a tray comprising a plurality of planar surfaces configured to support a prism-shaped battery along a long axis of the battery cradle,
a first side frame connected to a first side of the tray,
a second side frame attached to a second side of the tray, such that the first side frame is substantially parallel with second side frame, and
a plurality of protrusions on the first side frame, wherein at least some of the plurality of protrusions are configured to interlock with the plurality of sockets.

12. The battery cradle assembly of claim 11, wherein the compartment further comprises a door that covers the opening when the door is in a closed position, the door comprising a plurality of electrical contacts that make contact with a corresponding number of cylindrically-shaped batteries when the battery cradle is carrying cylindrically-shaped batteries and is secured within the compartment.

13. The battery cradle assembly of claim 11, wherein the compartment further comprises:
a rear wall on which a plurality of electrical contacts are disposed;
a door that covers the opening when closed, the door comprising a plurality of electrical contacts,
wherein the plurality of electrical contacts on the rear wall and the plurality of contacts on the door make contact with a corresponding number of cylindrically-shaped batteries when the battery cradle is carrying a plurality of cylindrically-shaped batteries and is secured within the compartment.

14. The battery cradle assembly of claim 13, wherein the plurality of cylindrically-shaped batteries are electrically connected in pairs such that each pair of cylindrical batteries is series with one another and in parallel with other pairs of the cylindrical batteries.

15. The battery cradle assembly of claim 13, wherein the tray further comprises one or more depressions along axes parallel to a short axis of the cradle, wherein each depression is configured to accommodate a cylindrically-shaped battery of the plurality of cylindrically-shaped batteries.

16. The battery cradle assembly of claim 15, wherein
the first side frame has a first set of recesses,
the second side frame has a second set of recesses,
each of the first set of recesses forms a pair with one of the second set of recesses so as to constitute a plurality of recess pairs,
each of the one or more depressions is aligned with a respective one of the plurality of recess pairs along an axis generally parallel to the first axis.

17. The battery cradle of claim 16, wherein the tray further comprises a plurality of slats, each planar surface being formed on a respective slat of the plurality.

18. The battery cradle of claim 17, wherein
each of the first set of recesses forms a pair with one of the second set of recesses so as to constitute a plurality of recess pairs,
each of the plurality of slats is offset along an axis generally parallel to the second axis with respect to the plurality of recess pairs.

19. A battery cradle assembly for a model vehicle, the battery cradle assembly comprising:
a chassis having an interior upper surface, an interior lower surface, and an interior rear surface that define a battery compartment having an opening;
a plurality of sockets formed on the interior upper surface, each of the plurality of sockets having a dovetail-shaped hole; and
a battery cradle comprising
a tray comprising a plurality of slats configured to support a prism-shaped battery,
a first frame connected to a first side of the tray, the first frame comprising a plurality of extensions, each extension comprising a dovetail at its distal end,
a second side frame attached to a second side of the tray, such that the first side frame is substantially parallel with second side frame,
wherein the battery cradle is configured to slide into the battery compartment so that the dovetails interlock with the dovetail-shaped holes of the plurality of sockets.

20. The battery holder assembly of claim 19, further comprising:
a plurality of sockets formed on the interior lower surface, each of the plurality of sockets having a dovetail-shaped hole;
a plurality of protrusions on the bottom of the tray, each of the plurality of protrusions on the bottom of the tray having a dovetail at its distal end such that, which the battery cradle slides into the battery compartment, the dovetails of the extensions on the bottom of the tray interlock with the dovetail-shaped holes of the plurality of sockets.
